(19) United States
(12) Patent Application Publication
(10) Pub. No.: US 2012/0139586 A1
(43) Pub. Date: Jun. 7, 2012

(54) FREQUENCY SYNTHESIZER AND FREQUENCY SYNTHESIZING METHOD

(75) Inventors: Furkan DAYI, Stuttgart (DE); Stefan KOCH, Oppenweiler (DE)

(73) Assignee: Sony Corporation, Tokyo (JP)

(21) Appl. No.: 13/306,407

(22) Filed: Nov. 29, 2011

(30) Foreign Application Priority Data
Dec. 1, 2010 (EP) 10193257.2

(51) Int. Cl. H03B 21/00

(52) U.S. Cl. 327/105

(57) ABSTRACT

The present invention relates to a frequency synthesizer comprising:
a reference signal source that provide a first reference signal,
a frequency signal generation unit that generates a synthesized frequency output signal at a predetermined frequency,
a mixing unit that mixes said synthesized frequency output signal with a frequency tuning signal and outputs a mixer signal,
a frequency tuning unit that provides said frequency tuning signal, said frequency tuning unit comprising a first frequency tuning sub-unit and a second frequency tuning sub-unit which alternately provide said frequency tuning signal, wherein, while one of the first and second frequency tuning sub-units is providing the frequency tuning signal, the other of the first and second frequency tuning sub-units is preparing for providing the frequency tuning signal, and
a frequency selection unit that selects a desired frequency range from said mixer signal and outputs a frequency synthesizer output signal.

### CROSS-REFERENCE TO RELATED APPLICATIONS

The present application claims priority of European patent application 10193257.2 filed on Dec. 1, 2010.

### FIELD OF THE INVENTION

The present invention relates to a frequency synthesizer and a corresponding frequency synthesizing method.

### BACKGROUND OF THE INVENTION

Frequency synthesizers are key building blocks for many microwave systems. They are found in many modern devices, including radio receivers, mobile telephones, satellite receivers, GPS systems, radars, etc. There are three main synthesizer architectures, in particular direct analog, direct digital and indirect (Phase Locked Loop) synthesizers. The requirements of the microwave systems are getting tough, so that the known synthesizers cannot fulfill requirements such as phase noise, switching speed, fine resolution, and frequency sweep. Recently, new hybrid architectures were developed which combines direct digital synthesizer (DDS) and phase locked loops (PLL) which, however, can also not fulfill all these requirements.

Millimeter wave/sub-THz frequency synthesizers which can generate ultra-broadband signals with fine frequency resolution and low phase noise and which can sweep linearly are not available and not known in the art. There are synthesizer architectures known having either limited bandwidth (as e.g. the architecture described in Dengler, R. J., Cooper, K. B., Llombart, N., Chattopadhyay, G., Bryllert, T., Mehdi, I., Siegel, P. H., “Toward real-time penetrating imaging radar at 670 GHz,” Microwave Symposium Digest, 2009 MTT '09, IEEE MTT-S International, pp. 941-944, 7-12 Jun. 2009), or coarse frequency resolution (using e.g. a PLL), or high phase noise (high multiplication factor), or combinations of these features (but not having all these features).

Dengler, R. J., Cooper, K. B., Llombart, N., Chattopadhyay, G., Bryllert, T., Mehdi, I., Siegel, P. H., “Toward real-time penetrating imaging radar at 670 GHz,” Microwave Symposium Digest, 2009 MTT '09, IEEE MTT-S International, pp. 941-944, 7-12 Jun. 2009 describes an imaging THz radar system in which an up-converter is used to mix a first fixed (high) frequency signal from a synthesizer with a second tunable (lower) frequency signal from a tunable source (chirper). The desired band of the output signal of the mixer is selected by use of a filter.

### BRIEF SUMMARY OF THE INVENTION

It is an object of the present invention to provide a frequency synthesizer and a corresponding frequency synthesizing method providing as many of the above mentioned features as possible, i.e. providing a large bandwidth, fine frequency resolution and low phase noise. Further, the ability to perform a continuous, preferably linear frequency sweep (required e.g. for radar applications) shall preferably be provided.

According to an aspect of the present invention there is provided a frequency synthesizer comprising:
a reference signal source that provides a first reference signal,
a frequency signal generation unit that generates a synthesized frequency output signal at a predetermined frequency,
a mixing unit that mixes said synthesized frequency output signal with a frequency tuning signal and outputs a mixer signal,
a frequency tuning unit that provides said frequency tuning signal, said frequency tuning unit comprising a first frequency tuning sub-unit and a second frequency tuning sub-unit which alternately provide said frequency tuning signal, wherein, while one of the first and second frequency tuning sub-units is providing the frequency tuning signal, the other of the first and second frequency tuning sub-units is preparing for providing the frequency tuning signal, and
a frequency selection unit that selects a desired frequency range from said mixer signal and outputs a frequency synthesizer output signal.

According to a further aspect of the present invention there is provided a corresponding frequency synthesizing method comprising the steps of:
generating a synthesized frequency output signal at a predetermined frequency,
down-converting said synthesized frequency output signal into said feedback signal,
mixing said synthesized frequency output signal with a frequency tuning signal and outputting a mixer signal,
alternately providing said frequency tuning signal by a first frequency tuning sub-unit and a second frequency tuning sub-unit, wherein, while one of the first and second frequency tuning sub-units is providing the frequency tuning signal, the other of the first and second frequency tuning sub-units is preparing for providing the frequency tuning signal, and
selecting a desired frequency range from said mixer signal and outputting a frequency synthesizer output signal.

Preferred embodiments of the invention are defined in the dependent claims. It shall be understood that the claimed frequency synthesizing method has similar and/or identical preferred embodiments as the claimed frequency synthesizer and as defined in the dependent claims.

The present invention is based on the idea that the base signals (i.e. the synthesized frequency output signal from the frequency signal generation unit) are generated by good phase noise oscillators (e.g. oscillators having a higher quality factor in the resonator tank of the oscillator). This kind of oscillators has very narrow bandwidth. However, fixed frequencies are required from the frequency signal generation unit. Afterwards, by mixing this frequency (i.e. the synthesized frequency output signal) with the frequency tuning signal from the frequency tuning unit and selecting the desired band of the mixer signal, a very low phase noise signal (the frequency synthesizer output signal), e.g. in the millimeter wave frequency band, can be generated (advantageously having a much larger bandwidth than signals that can be obtained by known frequency synthesizers.

Thus, with the frequency synthesizer and the frequency synthesizing method according to the present invention, ultra-broadband signals (e.g. in the frequency range 480-960 GHz; according to a preferred embodiment of the invention, this frequency is achieved by applying an additional frequency multiplication) with fine frequency resolution, high linearity, high chirp rate and good phase noise can be generated.

Further, as proposed in preferred embodiments of the present invention, different frequency bands (e.g. an upper side band and a lower side band of the mixer signal) can be used continuously with smooth transition between them, and a high linearity during frequency sweep can at the same time be achieved.

Generally, said frequency signal generation unit may simply comprise one (or more) oscillator, e.g. a dielectric resonator oscillator, for generating said synthesized frequency output signal at a predetermined frequency (in case of two or more oscillators at different frequencies). In a preferred embodiment, however, said frequency signal generation unit comprises at least one (preferably two or more) frequency signal generation loop circuit including a phase detector that compares the frequency and/or phase of a feedback signal received from a feedback loop to the phase of said first reference signal to obtain a control signal, an oscillator that generates a synthesized frequency output signal based on said control signal, and a feedback loop including a frequency down-conversion unit that down-converts said synthesized frequency output signal into said feedback signal. One of the advantages of such an embodiment is significantly better performance with regard to phase noise.

According to another aspect the present invention provides a frequency synthesizer comprising:
a reference signal providing means for providing a first reference signal,
a frequency signal generation means for generating a synthesized frequency output signal at a predetermined frequency,
a mixing means for mixing said synthesized frequency output signal with a frequency tuning signal and outputs a mixer signal,
a frequency tuning means for providing said frequency tuning signal, said frequency tuning means comprising a first frequency tuning sub-means and a second frequency tuning sub-means which alternately provide said frequency tuning signal, wherein, while one of the first and second frequency tuning sub-means is providing the frequency tuning signal, the other of the first and second frequency tuning sub-means is preparing for providing the frequency tuning signal, and
a frequency selection means for selecting a desired frequency range from said mixer signal and outputs a frequency synthesizer output signal.

### BRIEF DESCRIPTION OF THE DRAWINGS

These and other aspects of the present invention will be apparent from and explained in more detail below with reference to the embodiments described hereinafter. In the following drawings

FIG. 1 shows a block diagram of an embodiment of a known frequency synthesizer,

FIG. 2 shows a diagram illustrating frequency sweeping with the known frequency synthesizer,

FIG. 3 shows a block diagram of a first embodiment of a frequency synthesizer according to the present invention,

FIG. 4 shows a block diagram of a first embodiment of a frequency signal generation unit according to the present invention,

FIG. 5 shows a block diagram of a second embodiment of a frequency signal generation unit according to the present invention,

FIG. 6 shows a block diagram of a first embodiment of a frequency tuning unit according to the present invention,

FIG. 7 shows a block diagram of a second embodiment of a frequency tuning unit according to the present invention,

FIG. 8 shows a block diagram of a first embodiment of a frequency selection unit according to the present invention,

FIG. 9 shows a block diagram of a second embodiment of a frequency selection unit according to the present invention,

FIG. 10 shows a block diagram of a third embodiment of a frequency selection unit according to the present invention,

FIG. 11 shows a diagram illustrating continuous linear frequency sweeping with the frequency synthesizer according to the present invention, and

FIG. 12 shows a block diagram of a third embodiment of a frequency signal generation unit according to the present invention.

### DETAILED DESCRIPTION OF THE INVENTION

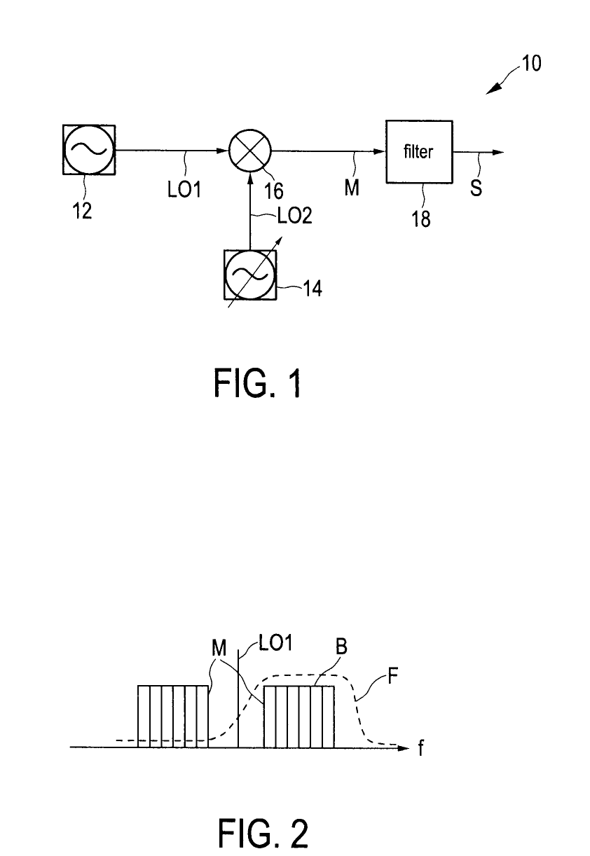

FIG. 1 shows a block diagram of a simple embodiment of a known frequency synthesizer 10. It comprises a first oscillator 12, e.g. a DRO (Dielectric resonator oscillator), providing a first local oscillator signal LO1 having a fixed (stable) frequency. Further, it comprises a second tunable oscillator 14, e.g. a tunable voltage controlled oscillator (VCO), providing a second local oscillator signal LO2 having a tunable frequency. The first local oscillator signal LO1 and the second local oscillator signal LO2 are mixed by a mixer 16 resulting in mixer signal M, which is filtered by a (preferably switchable) filter 18 to select the desired frequency band a synthesizer output signal S. Such a frequency synthesizer is, for instance, generally known from Dengler, R. J., Cooper, K. B., Llombart, N., Chattopadhyay, G., Bryllert, T., Mehdi, I., Siegel, P. H., “Toward real-time penetrating imaging radar at 670 GHz,” Microwave Symposium Digest, 2009 MTT '09, IEEE MTT-S International, pp. 941-944, 7-12 Jun. 2009.

FIG. 2 shows a diagram illustrating frequency sweeping with the known frequency synthesizer as depicted in FIG. 1. The first local oscillator signal LO1 is mixed to the mixer signal M, which is filtered by the filter having a filter curve F to select the desired frequency band B, in which a sweep of the output frequency of the synthesizer output signal S is achieved by varying the frequency of the second local oscillator signal LO2.

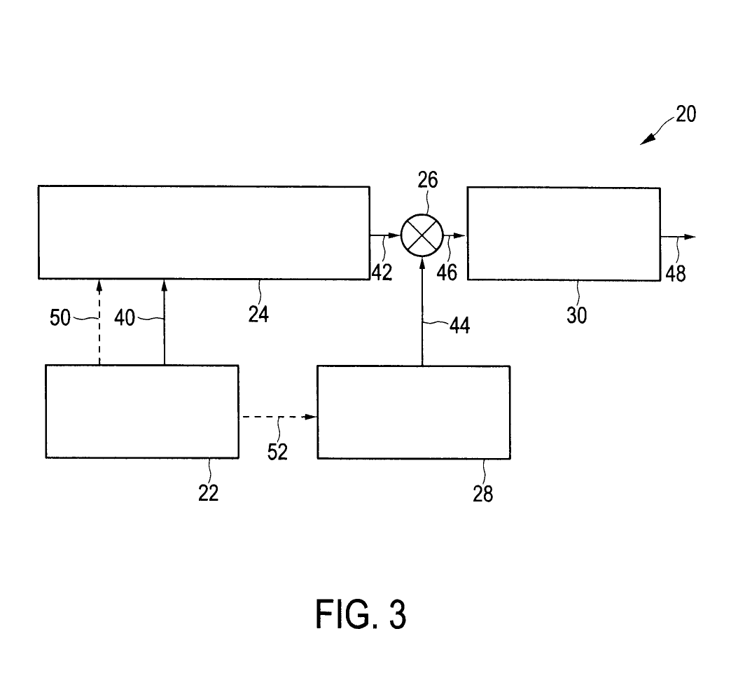

FIG. 3 shows a block diagram of a first embodiment of a frequency synthesizer 20 according to the present invention. The frequency synthesizer 20, which is preferably a mm-wave/sub-THz frequency synthesizer, comprises a reference signal source 22 that provides a first reference signal 40. A frequency signal generation unit 24 generates a synthesized frequency output signal 42 at a predetermined frequency by use of said first reference signal 40. Said synthesized frequency output signal 42 is mixed with a frequency tuning signal 44 by a mixing unit 26 which outputs a mixer signal 46. Said frequency tuning signal 44 is provided by a frequency tuning unit 28. A frequency selection unit 30 selects a desired frequency range from said mixer signal 46, multiplies the frequency and outputs a frequency synthesizer output signal 48.

If needed, as in some embodiments and depending on the particular implementation of the frequency signal generation unit 24 and/or the frequency tuning unit 28, further reference signals may be provided by the reference signal source 22. Such further (low phase noise) reference signals may include (low phase noise) reference signals 50 for phase detectors and/or necessary low phase noise LO (local oscillator) signals for mixers provided in particular implementations of the frequency signal generation unit 24, and/or low phase noise reference signals (clocks) 52 for direct digital synthesizers (DDS) provided in particular implementations of the frequency tuning unit 28.

In addition, a control unit (not shown) may be provided for controlling the elements of the frequency synthesizer 20.

The frequency signal generation unit 24 provides certain fixed frequencies with a frequency difference f_{D}. The frequency tuning unit 28 provides a linear continuous sweep with the bandwidth B. The frequency selection unit 30, which preferably also includes a multiplication unit, selects the desired frequency band from the mixer signal 46, e.g. in an embodiment either the lower sideband or the higher sideband. Then, the signal from the selected frequency band is preferably filtered, amplified and multiplied. Thus, a continuous, linear, ultra-broadband frequency sweep in a desired frequency range, e.g. in the mm-wave/THz frequency range, can be realized.

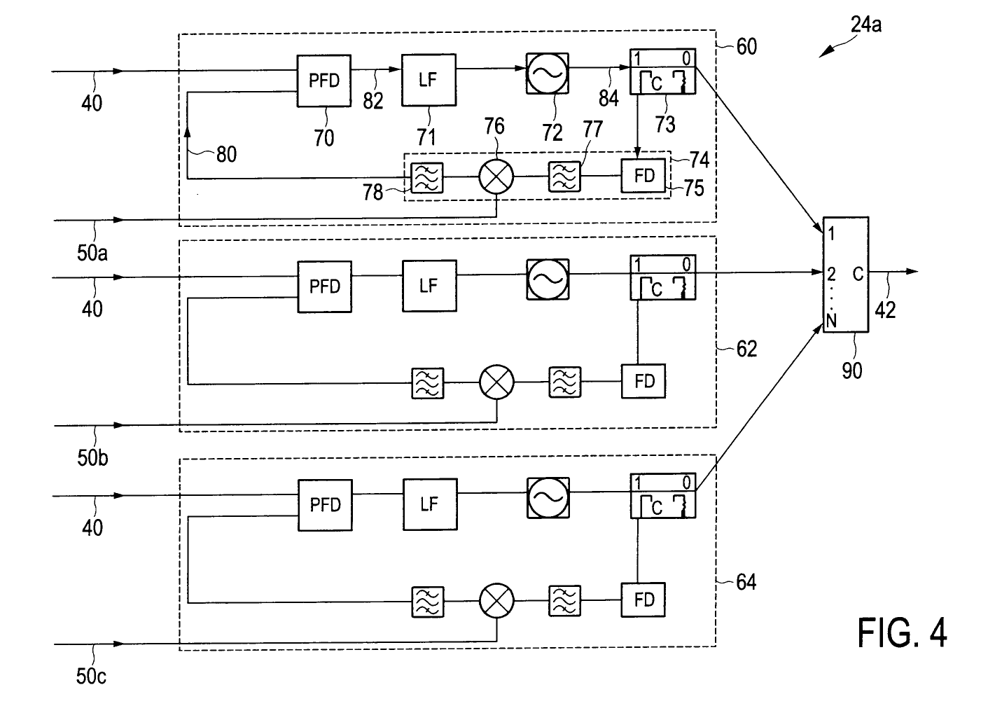

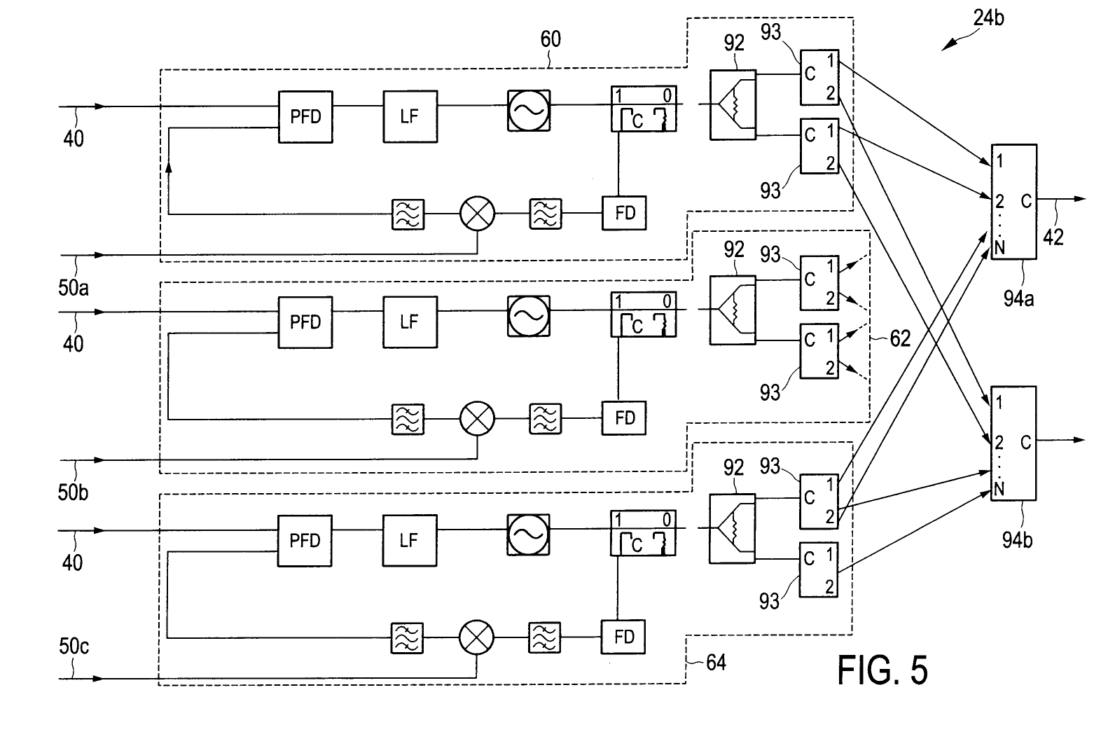

Preferred embodiments of the frequency signal generation unit 24a, 24b are shown in FIGS. 4 and 5. Generally, the frequency signal generation unit 24 comprises at least one frequency signal generation loop circuit up to any number of frequency signal generation loop circuits, while in the exemplary embodiments shown in FIGS. 4 and 5 the frequency signal generation unit 24a, 24b comprises three frequency signal generation loop circuits 60, 62, 64. In general, there is no upper limit, reasonable numbers are 2 to 6, in particular 2 to 4, frequency signal generation loop circuits.

By way of taking frequency signal generation loop circuit 60 as an example a preferred embodiment of the frequency signal generation loop circuits 60, 62, 64 shall be explained.

A phase detector 70 (also called phase frequency detector; PFD) compares the frequency and/or phase of a feedback signal 80 received from a feedback loop to the frequency and/or phase of said first reference signal 40 (in particular, detects frequency and/or phase differences) to obtain a control signal 82. A loop filter 71 is coupled to the output of the phase detector 70 for filtering the control signal 82 output from the phase detector 70. A controlled oscillator 72, e.g. a voltage controlled oscillator (VCO), is coupled to the output of the loop filter 71 and generates a synthesized frequency output signal 84 based on said control signal 82. Said synthesized frequency output signal 84 is output by an output unit 73, e.g. a splitter, which also provides the synthesized frequency output signal 84 to a feedback loop including a frequency down-conversion unit 74 that down-converts said synthesized frequency output signal 84 into said feedback signal 80.

The frequency down-conversion unit 74 preferably comprises a frequency divider 75 and a mixer 76, which down-mixes the output signal of the frequency divider 75 with a second reference signal 50a provided by said reference signal source 22 to obtain said feedback signal 80. Further, in some embodiments additional filters 77, 78 (in particular band-pass filters) in front of and/or behind the mixer 76 are provided in the feedback loop.

The VCOs 72 are preferably narrowband (high Q) oscillators to have very good phase noise characteristics. The mixer 76 in each frequency signal generation loop circuit 60, 62, 64 down-converts the synthesized frequency output signal 84 to the phase detector frequency. To cover a broader spectral range, i.e. to enable a frequency sweep over a broader bandwidth, the mixers 76 of the various frequency signal generation loop circuits 60, 62, 64 are provided with different second reference signals 50a, 50b, 50c and the controlled oscillators 72 are accordingly working at different frequencies. The frequencies of the oscillators are chosen in a way that the “chain” of upper and lower sidebands (see FIG. 2) is preferably, but not necessarily, continuous. If it is not continuous, individual frequency bands can be generated. If necessary, a frequency divider 75 with lowest division ratio may be used. In order to achieve the best phase noise, VCOs 72 with nearly fixed frequency and no frequency dividers 75 are used in the feedback loop.

The embodiment of the frequency signal generation unit 24a shown in FIG. 4 is particularly used if the mixing unit 26 (see FIG. 3) comprises a double side band (DSB) mixer. If the mixing unit 26 (see FIG. 3) comprises a single side band (SSB) mixer the frequency signal generation unit 24b shown in FIG. 5 is particularly used. For the phase detector frequency the highest possible frequency is selected to maintain good phase noise performance. The switch 90 in the frequency signal generation unit 24a selects one fixed frequency which is generated in one of the loop circuits 60, 62, 64 and outputs it to the DSB mixer. In the frequency signal generation unit 24b, 90° hybrid couplers 92 (or 90° phase shifters) are used. Both, the original synthesized frequency output signal 84a and the 90° phase shifted synthesized frequency output signal 84b are provided via output units 93 to two switches 94a, 94b. The output of these two switches 94a, 94b are connected to the two different IF inputs of the SSB mixer 26. By use of these two switches 94a, 94b the desired side band after the up-conversion can be selected.

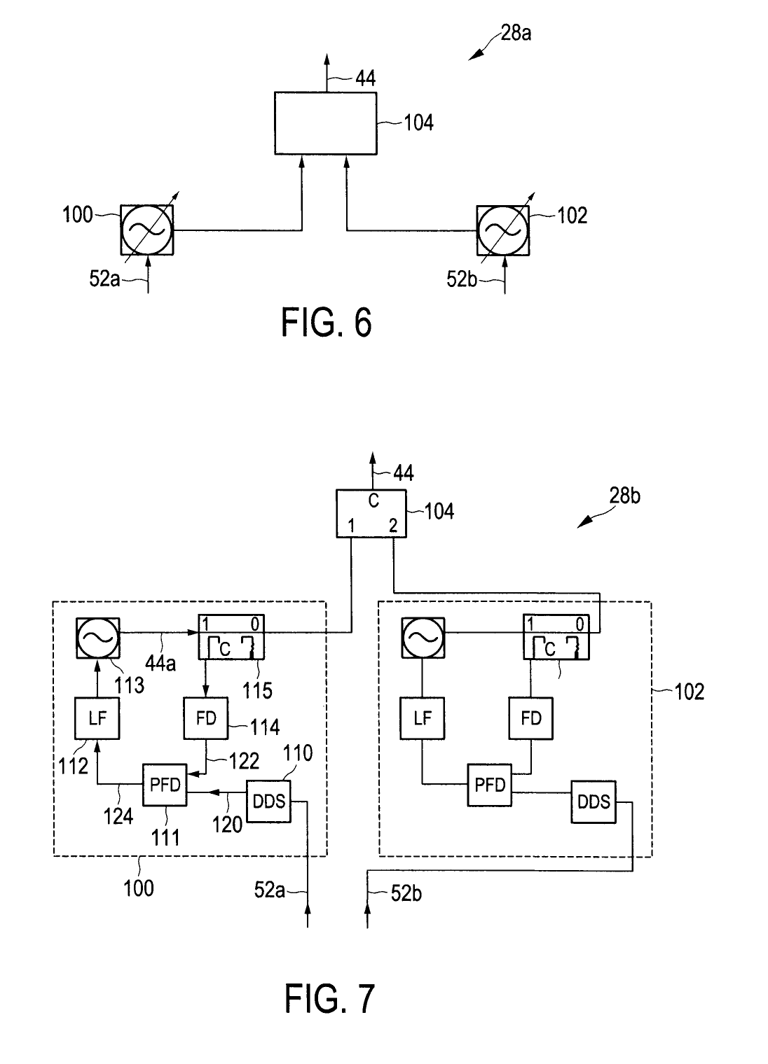

A first embodiment of a frequency tuning unit 28a is depicted in FIG. 6. The frequency tuning unit generally comprises a first frequency tuning sub-unit 100 and a second frequency tuning sub-unit 102 which alternately (e.g. switched by a switch 104) provide the frequency tuning signal 44. Hence, while one of the first and second frequency tuning sub-units 100, 102 is providing the frequency tuning signal 44, the other of the first and second frequency tuning sub-units 100, 102 is preparing for providing the frequency tuning signal 44, i.e. can already tune to the desired frequency that shall be delivered by said other frequency tuning sub-unit, e.g. in order to provide a continuous linear frequency sweep.

In a simple embodiment as shown in FIG. 6 the first and second frequency tuning sub-units 100, 102 are implemented as tunable oscillators, e.g. as tunable VCOs. Each of the first and second frequency tuning sub-units 100, 102 receives an individual (third) reference signal 52a, 52b, in particular a control voltage, e.g. from the reference signal source 22, to control the first and second frequency tuning sub-units 100, 102.

Other embodiments of the frequency tuning unit 28 are available as, for instance, shown in FIG. 7, in which a more detailed embodiment of a frequency tuning unit 28b is depicted. In this embodiment each frequency tuning sub-unit 100, 102 is implemented as a hybrid DDS/PLL loop as, for instance, described in Stelzer, A.; Kolmhofer, E.; Scheiblhofer, S., “Fast 77 GHz chirps with direct digital synthesis and phase locked loop”, Microwave Conference Proceedings, 2005, APMC 2005, Asia-Pacific Conference Proceedings, vol. 3, 4-7 Dec. 2005. Taking the tuning sub-unit 100 as an example, it comprises a direct digital synthesizer 110 that generates a DDS signal 120 from a third fixed-frequency reference signal 52a, a tuning phase detector 111 that compares the phase of a tuning frequency divider output signal 122 received from a tuning feedback loop to the phase of the DDS signal 120 to obtain a tuning control signal 124, a loop filter 112 that filters said tuning control signal 124, a tuning oscillator (e.g. a VCO) 113 that generates said tuning frequency output signal 44a of said frequency tuning sub-unit 100 from said based on said (filtered) tuning control signal, and a tuning frequency divider 114 in the feedback loop that frequency divides the tuning frequency output signal 44a to obtain said tuning frequency divider output signal 122. The tuning frequency output signal 44a is output by an output unit 115, e.g. a splitter, which also provides the tuning frequency output signal 44a to the frequency divider 114 in the feedback loop.

Such a hybrid structure provides a very linear high resolution frequency sweeping. In order to have continuous sweep at the output of the frequency synthesizer, two hybrid DDS/PLL loop circuits, i.e. the frequency tuning sub-units 100, 102 are implemented in this embodiment. While one loop circuit is providing the LO input of the mixing unit 26, the other loop circuit is getting ready for the next sweep. By use of the switch 104 the necessary loop circuit is selected. Depending on the selection the upper frequency band or the lower frequency of the RF output of the mixing unit 26, the sweep direction of the hybrid DDS/PLL loop circuit is determined.

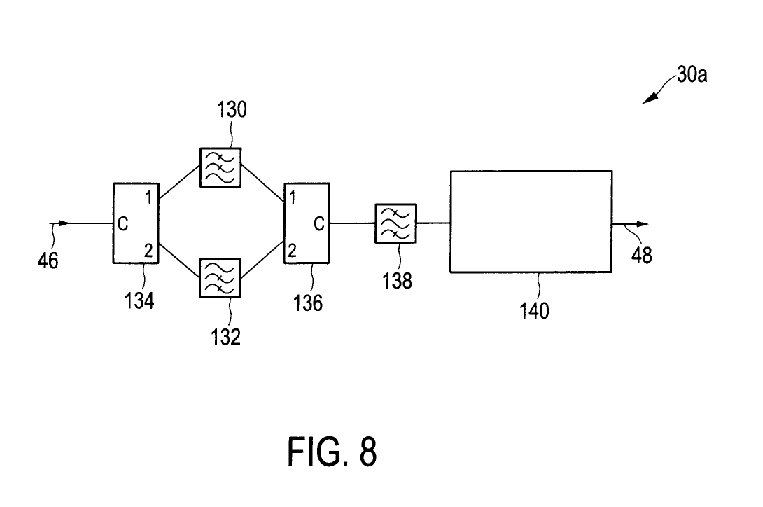

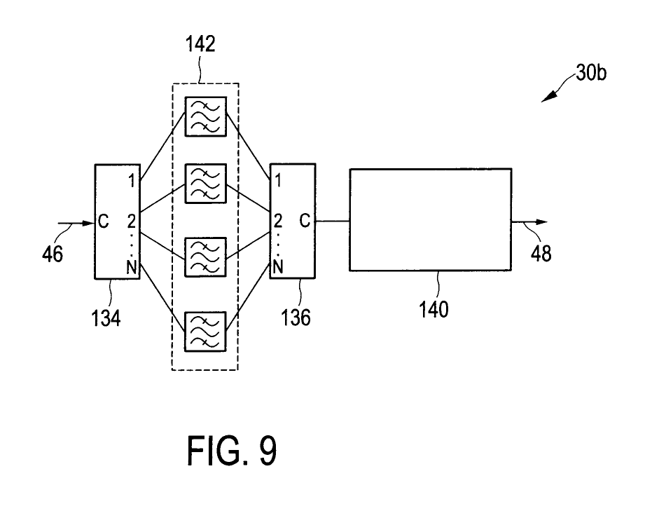

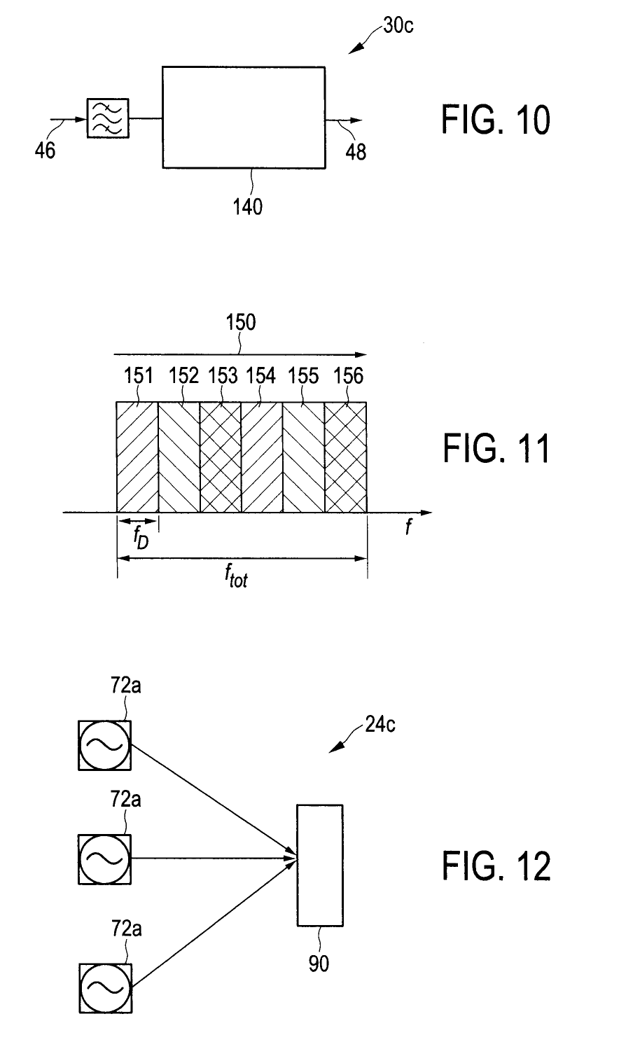

Various embodiments of the frequency selection unit 30 are shown in FIGS. 8 to 10. If the mixing unit 26 includes a DSB mixer, which is preferably coupled to an embodiment of the frequency signal generation unit 24a as shown in FIG. 4, embodiments of the frequency selection unit 30a, 30b as shown in FIGS. 8 and 9 are preferred, while the embodiment of the frequency selection unit 30c as shown in FIG. 10 is preferred if the mixing unit 26 includes an SSB mixer, which is preferably coupled to an embodiment of the frequency signal generation unit 24b as shown in FIG. 5.

The embodiment of the frequency selection unit 30a shown in FIG. 8 comprises a low-pass filter 130 and a high-pass filter 132 coupled in parallel between switches 134, 136 for selecting the upper or lower side band from said mixer signal 46 provided by the DSB mixer included in the mixing unit 26 in one embodiment. Preferably, a band pass filter 138 is coupled to the output of the second switch 136, which band pass-filter 138 covers the complete (desired) bandwidth and is used to suppress unwanted spurious signals. The output signal of the band-pass filter 138 is then preferably multiplied, amplified and filtered in a post-processing unit 140, e.g. including a multiplicator, an amplifier and a filter.

The embodiment of the frequency selection unit 30b shown in FIG. 9 comprises a filter bank 142 of three or more filters coupled in parallel between switches 134, 136 for selecting a desired frequency band from said mixer signal 46, in particular for selecting either the lower or upper side band of the mixing signal 46 provided by the DSB mixer included in the mixing unit 26 in one embodiment.

The embodiment of the frequency selection unit 30c shown in FIG. 10 comprises a band-pass filter 144 for selecting the desired frequency band from said mixer signal 44 provided by the SSB mixer included in the mixing unit 26 in one embodiment. Preferably, the band-pass filter covers the complete (desired) frequency band. The image suppression (i.e. the suppression of the undesired frequency band) has been done already in SSB mixer (to a certain degree). If further suppression is necessary, additional filters may be added.

FIG. 11 shows a diagram illustrating continuous linear frequency sweeping with the frequency synthesizer according to the present invention, in particular using an embodiment of a frequency signal generation unit 24a or 24b as shown in FIG. 4 or FIG. 5 having three frequency signal generation loop circuit 60, 62, 64. With the proper controlling of the frequency tuning signal 44, in particular the tuning frequency of said frequency tuning signal 44, by the frequency tuning unit 28 a very broadband continuous sweep, as indicated by the arrow 150 can be realized.

In particular, as shown in FIG. 11, the total bandwidth fₜₒₜ that can be covered by the continuous sweep 150 corresponds to six times the frequency difference f_{D} representing the bandwidth of each of the six frequency band (after multiplication of this low phase noise mixing signal 46, the bandwidth is even much broader). These frequency bands are generated as follows (assuming the use of the embodiment of the frequency signal generation unit 24a and the use of a DSB mixer in the mixing unit 26).

The first frequency band 151 is the lower side band after up-conversion by the first frequency signal generation loop circuit 60. The second frequency band 151 is the lower side band after up-conversion by the second frequency signal generation loop circuit 62. The third frequency band 153 is the lower side band after up-conversion by the third frequency signal generation loop circuit 64. The fourth frequency band 154 is the upper side band after up-conversion by the first frequency signal generation loop circuit 60. The fifth frequency band 155 is the upper side band after up-conversion by the second frequency signal generation loop circuit 62. The sixth frequency band 156 is the upper side band after up-conversion by the third frequency signal generation loop circuit 64.

Hence, if, for instance, the synthesized frequency output signal 42 from the first frequency signal generation loop circuit 60 is switched onto the mixing circuit 26, the mixing signal 44 covers the first and fourth frequency bands 151, 154 having a considerable gap (in frequency direction) in between. Consequently, the requirements on the subsequent filter in the frequency selection unit 30 for filtering out the desired frequency band are less strict, i.e. the filter curve can be less steep as, for instance, in the known frequency synthesizers where there is no (or only a small) gap between neighboring frequency bands, as shown in FIG. 2.

An example for the frequency allocation in a practical implementation could be as follows (referring again to the example explained with reference to FIG. 11): It shall be assumed that the three frequency signal generation loop circuits 60, 62, 64 have fixed oscillator frequencies of 40, 45 and 50 GHz, respectively. The frequency tuning signal 44 is 5-10 GHz. This means that with the first frequency signal generation loop circuit 60 frequency bands 151, 154 at 30-35 GHz and 45-50 GHz, with the second frequency signal generation loop circuit 62 frequency bands 152, 155 at 35-40 GHz and 50-55 GHz, and with the third frequency signal generation loop circuit 64 frequency bands 153, 156 at 40-45 GHz and 55-60 GHz can be generated. Therefore, a frequency sweep from 30 GHz to 60 GHz can be performed.

Preferably, the sweep of the frequency tuning unit signal 44 should be in different directions for the lower side bands (i.e. the frequency bands 151, 152, 153) than the upper side bands (i.e. the frequency bands 154, 155, 156). If the multiplication factor is 16, the output frequency of the frequency synthesizer will be from 480 to 960 GHz. If the used DDS in the frequency tuning unit 28 works with 32 bit, the reference clock of the DDS is 1 GHz and the output of the DDS is 100 MHz, the signal at the output of the DDS will have 0.23 Hz resolution, and at the output 48 of the frequency synthesizer has a fine resolution of 368 Hz (in the 480-960 GHz band).

A simple embodiment of a frequency signal generation unit 24c is shown in FIG. 12. In this embodiment the frequency signal generation unit 24c comprises three oscillators 72a, in particular dielectric resonator oscillators, that generate a synthesized frequency output signal at a different predetermined frequency with sufficiently low phase noise. These oscillators thus replace the loop circuits 60, 62, 64 provided in the above explained embodiments.

It should be noted that particular elements used in the device and method of the present invention are generally known. This holds particularly for elements like loop filters, local oscillators, phase detectors, mixers and frequency dividers. Hence, in embodiments of the proposed frequency synthesizer standard elements can be used for those elements with the required settings and/or dimensions to achieve the desired effects.

The proposed frequency synthesizer can synthesize linear continuous frequency sweeps in microwave and millimeter wave frequencies. Any deterministic ultra-broadband frequency shapes can be generated, in particular in preferred embodiments using a digital signal generation in a DDS. The synthesized frequency has low phase noise in lower and higher in-band offset frequencies. The frequency synthesizer has very fine resolution (Hz), which mainly depends on the DDS performance. It is also capable of synthesizing multitude waveforms such as very linear, quadratic, cubic frequency chirps or deterministic deviations from linear frequency ramps.

The invention has been illustrated and described in detail in the drawings and foregoing description, but such illustration and description are to be considered illustrative or exemplary and not restrictive. The invention is not limited to the disclosed embodiments. Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measures cannot be used to advantage.

Any reference signs in the claims should not be construed as limiting the scope.

1. A frequency synthesizer comprising:
a reference signal source that provides a first reference signal,
a frequency signal generation unit that generates a synthesized frequency output signal at a predetermined frequency,
a mixing unit that mixes said synthesized frequency output signal with a frequency tuning signal and outputs a mixer signal,
a frequency tuning unit that provides said frequency tuning signal, said frequency tuning unit comprising a first frequency tuning sub-unit and a second frequency tuning sub-unit which alternately provide said frequency tuning signal, wherein, while one of the first and second frequency tuning sub-units is providing the frequency tuning signal, the other of the first and second frequency tuning sub-units is preparing for providing the frequency tuning signal, and
a frequency selection unit that selects a desired frequency range from said mixer signal and outputs a frequency synthesizer output signal.

2. The frequency synthesizer as claimed in claim 1,
wherein said frequency signal generation unit comprises at least one frequency signal generation loop circuit including a phase detector that compares the frequency and/or phase of a feedback signal received from a feedback loop to the phase of said first reference signal to obtain a control signal, an oscillator that generates a synthesized frequency output signal based on said control signal, and a feedback loop including a frequency down-conversion unit that down-converts said synthesized frequency output signal into said feedback signal.

3. The frequency synthesizer as claimed in claim 2,
wherein said frequency signal generation unit comprises two or more frequency signal generation loop circuits each comprising an oscillator that generates a synthesized frequency output signal at a different predetermined frequency.

4. The frequency synthesizer as claimed in claim 1,
wherein said frequency down-conversion unit of said one or more frequency signal generation loop circuits each comprises a mixer that mixes the synthesized frequency output signal of the oscillator of the respective frequency signal generation loop circuit with a second reference signal provided by said reference signal source to obtain said feedback signal.

5. The frequency synthesizer as claimed in claim 2 or 4,
wherein said one or more frequency signal generation loop circuits each comprises a loop filter coupled between the phase detector and the oscillator of the respective frequency signal generation loop circuit for filtering the respective control signal.

6. The frequency synthesizer as claimed in claim 2 or 4,
wherein said one or more frequency signal generation loop circuits each comprises a frequency divider coupled between the oscillator and the down-conversion unit of the respective frequency signal generation loop circuit that frequency divides the respective synthesized frequency output signal.

7. The frequency synthesizer as claimed in claim 2 or 4,
wherein said one or more frequency signal generation loop circuits each comprises a feedback filter coupled between the oscillator and the down-conversion unit and/or the down-conversion unit and the phase detector of the respective frequency signal generation loop circuit that filters said synthesized frequency output signal and/or said feedback output signal.

8. The frequency synthesizer as claimed in claim 3,
wherein said mixing unit comprises a double side band mixer and wherein said frequency signal generation unit comprises a switch for selecting one of the synthesized frequency output signals from one of the two or more frequency signal generation loop circuits as input signal for said double side band mixer.

9. The frequency synthesizer as claimed in claim 3,
wherein said mixing unit comprises a single side band mixer, wherein said two or more frequency signal generation loop circuits each comprises a 90° hybrid coupler or 90° phase shifter for outputting a first synthesized frequency output signal and a second synthesized frequency output signal that is 90° phase shifted with respect to the first synthesized frequency output signal, and wherein said frequency signal generation unit comprises two switches for selecting one pair of first and second synthesized frequency output signals from one of the two or more frequency signal generation loop circuits as input signals for said single side band mixer.

10. The frequency synthesizer as claimed in claim 1,
wherein said first and second frequency tuning sub-units each comprises a tunable oscillator, in particular a tunable voltage controlled oscillator.

11. The frequency synthesizer as claimed in claim 1,
wherein said first and second frequency tuning sub-units each comprises a tunable oscillator loop circuit including a direct digital synthesizer that generates a DDS signal from a third fixed-frequency reference signal, a tuning phase detector that compares the phase of a tuning frequency divider output signal received from a tuning feedback loop to the phase of the DDS signal to obtain a tuning control signal, a tuning oscillator that generates said tuning frequency output signal based on said tuning control signal, and a tuning frequency divider that frequency divides the tuning frequency output signal to obtain said tuning frequency divider output signal.

12. The frequency synthesizer as claimed in claim 1,
wherein said frequency tuning unit comprises a tuning switch coupled to the output of said first and second frequency tuning sub-units that switches between the output signals of said first and second frequency tuning sub-units to alternately provide said frequency tuning signal.

13. The frequency synthesizer as claimed in claim 8,
wherein said frequency selection unit comprises a low-pass filter and a high-pass filter coupled in parallel between switches for selecting the upper or lower side band from said mixer signal.

14. The frequency synthesizer as claimed in claim 8,
wherein said frequency selection unit comprises a filter bank of three or more filters coupled in parallel between switches for selecting a desired frequency band from said mixer signal.

15. The frequency synthesizer as claimed in claim 8,
wherein said frequency selection unit comprises a band-pass filter for selecting the desired frequency band from said mixer signal.

16. The frequency synthesizer as claimed in claim 1,
wherein said frequency signal generation unit comprises at least one oscillator, in particular a dielectric resonator oscillator, that generates a synthesized frequency output signal at a predetermined frequency.

17. The frequency synthesizer as claimed in claim 16,
wherein said frequency signal generation unit comprises two or more oscillators, in particular dielectric resonator oscillators, that generates a synthesized frequency output signal at a different predetermined frequency.

18. A frequency synthesizing method comprising:
generating a synthesized frequency output signal at a predetermined frequency,
down-converting said synthesized frequency output signal into said feedback signal,
mixing said synthesized frequency output signal with a frequency tuning signal and outputting a mixer signal,
alternately providing said frequency tuning signal by a first frequency tuning sub-unit and a second frequency tuning sub-unit, wherein, while one of the first and second frequency tuning sub-units is providing the frequency tuning signal, the other of the first and second frequency tuning sub-units is preparing for providing the frequency tuning signal, and
selecting a desired frequency range from said mixer signal and outputting a frequency synthesizer output signal.

19. A frequency synthesizer comprising:
a reference signal providing means for providing a first reference signal,
a frequency signal generation means for generating a synthesized frequency output signal at a predetermined frequency,
a mixing means for mixing said synthesized frequency output signal with a frequency tuning signal and outputs a mixer signal,
a frequency tuning means for providing said frequency tuning signal, said frequency tuning means comprising a first frequency tuning sub-means and a second frequency tuning sub-means which alternately provide said frequency tuning signal, wherein, while one of the first and second frequency tuning sub-means is providing the frequency tuning signal, the other of the first and second frequency tuning sub-means is preparing for providing the frequency tuning signal, and
a frequency selection means for selecting a desired frequency range from said mixer signal and outputs a frequency synthesizer output signal.
